(19) United States
(12) Patent Application Publication
(10) Pub. No.: US 2024/0223167 A1
(43) Pub. Date: Jul. 4, 2024

(54) PROCESS-VOLTAGE-TEMPERATURE TOLERANT REPLICA FEEDBACK PULSE GENERATOR CIRCUIT FOR PULSED LATCH

(71) Applicant: Intel Corporation, Santa Clara, CA (US)

(72) Inventors: Amit Agarwal, Hillsboro, OR (US); Steven K. Hsu, Lake Oswego, OR (US); Mark A. Anders, Hillsboro, OR (US); Ram K. Krishnamurthy, Portland, OR (US)

(21) Appl. No.: 18/091,970

(22) Filed: Dec. 30, 2022

(51) Int. Cl. H03K 4/94; H03K 3/037

(52) U.S. Cl. CPC H03K 4/94; H03K 3/037; H03K 19/20

(57) ABSTRACT

Embodiments herein relate to a pulse generator which provides first and second clock pulses to one or more pulsed latches, where the pulse generator replicates a delay of the pulsed latches in providing the first and second clock pulses. The pulse generator can include a replica of latch components in the pulsed latches such as a tri-state inverter, a transmission gate and inverters, where an output of the tri-state inverter is coupled to the transmission gate and to an input of the inverter, and an output of the inverter is coupled to an input of the tri-state inverter. The tri-state inverter can be a modified tri-state inverter with an output forced to “1” when a clock signal is “0.” In one approach, the latch components of the pulse generator are to write a logic 1 when a clock signal goes high.

### FIELD

The present application generally relates to the field of computing devices and more particular to a pulse generator for pulsed latches.

### BACKGROUND

High performance designs for modern microprocessors, discrete graphics, digital signal processors (DSP) and hardware accelerators in laptops and servers, for example, are increasingly important for emerging applications such as Artificial Intelligence (AI)/machine learning, autonomous driving, security/crypto currency and computer vison. Flip flops have been used as basic building block of sequential logic in digital integrated circuits which are used in these designs. More recently, the pulsed latch as a sequential element has been shown to reduce delays and power compared to flip-flop circuits. However, various challenges are presented in operating a pulsed latch.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 depicts an example of an interconnect mesh circuit with pulsed latches and repeater buses, according to various embodiments.

FIG. 2 depicts an example of a global pulse generator for a set of distributed latches, according to various embodiments.

FIG. 3 depicts an example of a local pulse generator circuit integrated with a multi-bit pulsed latch standard cell circuit, according to various embodiments.

FIG. 4A depicts an example of a comparative pulse generator circuit, according to various embodiments.

FIG. 4B depicts waveforms from the pulse generator circuit of FIG. 4A, where pulse evaporation occurs on nc1 and nc2, according to various embodiments.

FIG. 5A depicts an example of another comparative pulse generator circuit, according to various embodiments.

FIG. 5B depicts waveforms from the pulse generator circuit of FIG. 5A, where pulse evaporation occurs on nc2, according to various embodiments.

FIG. 6A1 depicts a replica feedback pulse generator circuit with a same latch cell as a pulsed latch with replica delay writing of a “0,” according to various embodiments.

FIG. 6A2 depicts waveforms consistent with the replica feedback pulse generator circuit of FIG. 6A1, according to various embodiments.

FIG. 6B1 depicts a replica feedback pulse generator circuit with a same latch cell as a pulsed latch with replica delay writing of a “1,” according to various embodiments.

FIG. 6B2 depicts waveforms consistent with the replica feedback pulse generator circuit of FIG. 6A1, according to various embodiments.

FIG. 6B3 depicts a circuit 657a which is an example implementation of the tri-state inverter 657 of FIG. 6B1, according to various embodiments.

FIG. 6B4 depicts a triple stack inverter pair circuit 705a which is an example implementation of the pair of inverters 705 of FIG. 6B1, according to various embodiments.

FIG. 7 depicts an example local replica feedback pulse generator integrated with a multi-bit pulsed latch standard cell circuit, according to various embodiments.

FIG. 8A depicts a global replica feedback pulse generator with a generated clock pulse nc2 routed to multiple pulsed latches, according to various embodiments.

FIG. 8B depicts a triple stack inverter circuit which is an example implementation of the inverters 805 and 813 of FIG. 8A, according to various embodiments.

FIG. 9 illustrates an example of components that may be present in a computing system 950 for implementing the techniques (e.g., operations, processes, methods, and methodologies) described herein.

### DETAILED DESCRIPTION

As mentioned at the outset, various challenges are presented in operating pulsed latches, which have been shown to reduce delays and power compared to flip-flop circuits, where the delays can constitute about 10-20% of the cycle time in high performance designs.

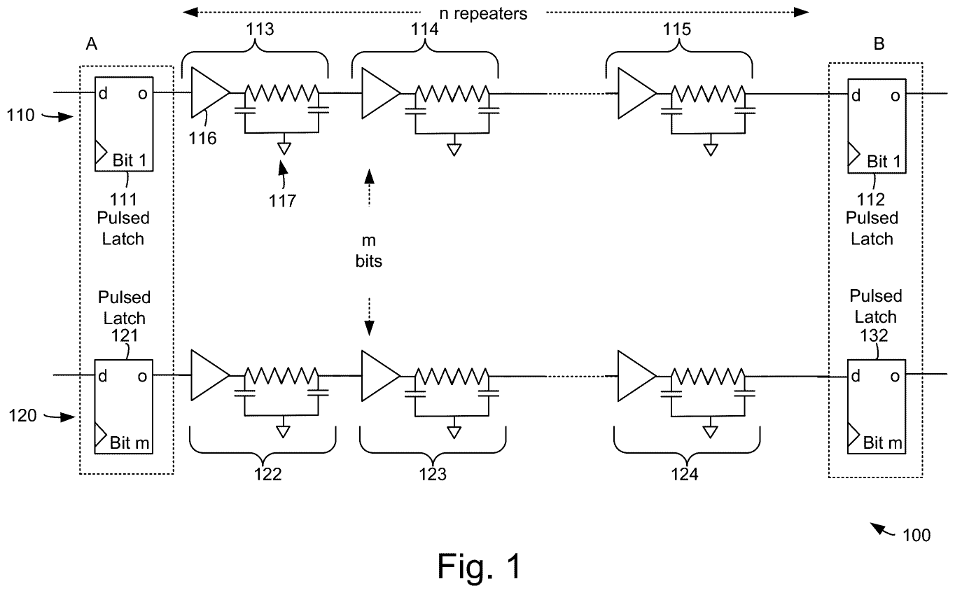

High-performance pulsed latch circuits are applicable in current/future frequency-constrained server interconnect mesh and graphics repeater buses, for example. These interconnect circuits send data from point A to B with a fixed interconnect and repeater delay and, by design, meet the extra hold time required by pulsed latches (see FIG. 1). However, the sequential delay constitutes almost 20-30% of the cycle time for such high-performance server mesh. Having a lower delay sequential like pulsed latch helps meet the frequency target and can enable more routing track by wire optimization at iso-frequency to achieve higher bandwidth. A pulsed latch can also be used as a means to fix outlier maximum delay paths, helping to bring those paths closer to the overall timing wall, while at the same time trying to keep the number of pulsed latches inserted low and the associated pulse generator dynamic power cost manageable.

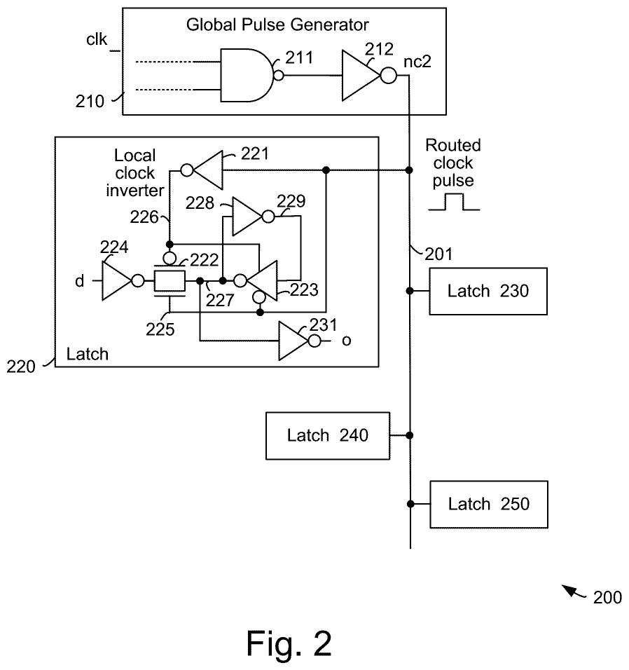

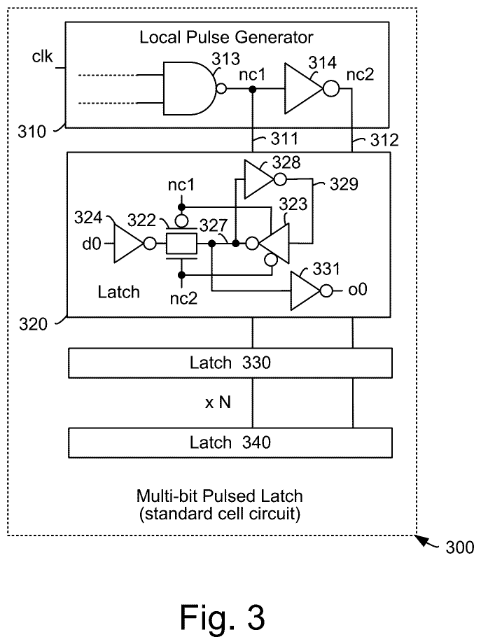

A pulsed latch is functionally equivalent to a flip-flop and designed using a latch which is driven by a small clock pulse, derived from a main clock using a pulse generator circuit. The pulse generator circuit can either be shared globally (see FIG. 2) where a generated pulsed clock is routed to multiple latches, or can be local to a multi-bit latch (see FIG. 3) and integrated as part of standard cell circuit. However, generating these clock pulses reliably while maintaining low hold time margin is extremely challenging under process variations. A small clock pulse width is essential to reduce hold time, while a large pulse width is needed to prevent pulse evaporation and writability issue. This conflicting pulse width requirement gets worse with clock load/slope under process-voltage-temperature (PVT) variations.

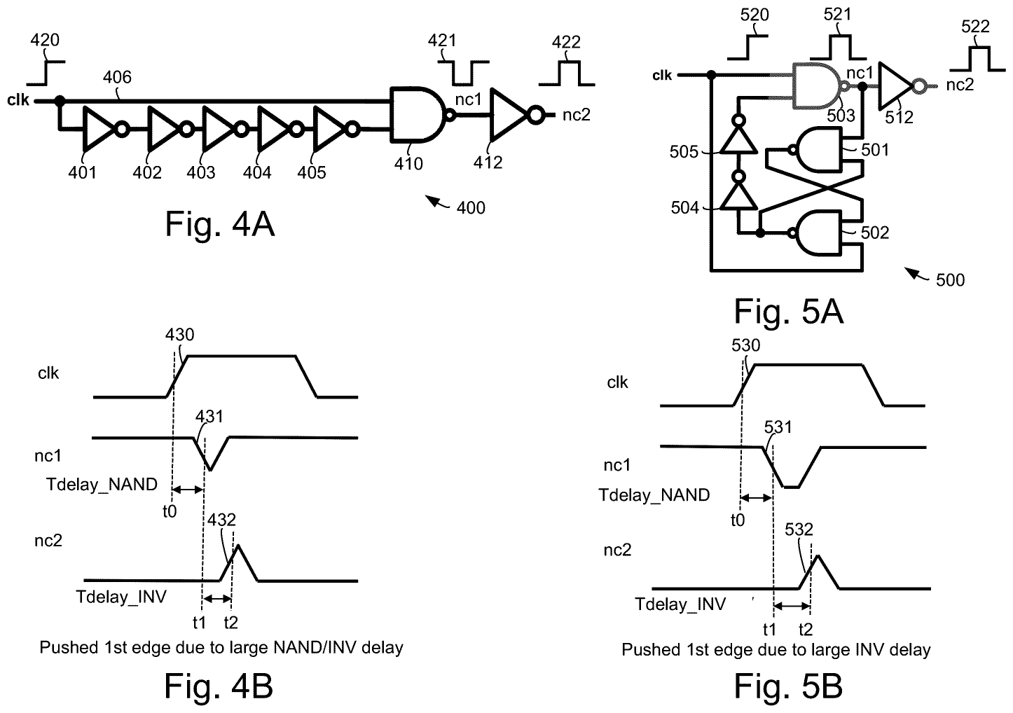

In one possible solution, a pulse generator samples a clock input and a delayed clock signal through a chain of inverters feeding to a NAND gate followed by an inverter to create a clock pulse (see FIG. 4A). However, in this approach, the second edge of the pulse has a diverged path with respect to the first edge and may result in pulse evaporation under process variations, which worsens with poor clock slope and large load/slope on output clock nodes of the pulse generator (see FIG. 4B).

In another possible solution, a pulse generator feeds the output of a NAND gate though a set-reset (SR) latch to create a delayed signal (see FIG. 5A). However, this results in the second edge of the pulse at the output of NAND gate being dependent on the first edge (see FIG. 5B). This dependency makes the pulse generator tolerant against pulse evaporation under PVT variations and degraded load/slope conditions. However, the pulse generator still has diverged paths between the first and second edges at the output of an inverter, which may result in pulse evaporation. Moreover, the pulse delays produced in these possible solutions are derived from an inverter chain/SR latch delay and do not track the actual pulsed latch write delay across PVT corners, resulting in latch writability issues.

The techniques and apparatuses provided herein address the above and other issues, making pulsed latches a viable option to reduce delays and power compared to flip-flop circuits. Integrating the pulse generator locally with a multi-bit latch also solves previous challenges of routing/timing analysis of pulsed latches. Today's computer aided design (CAD) tools can insert multi-bit flip-flops at the block level in different types of computing devices.

In one aspect, a replica pulse generator circuit is provided which feeds back both NAND and inverter outputs to a replica latch clock device generating a latch write delay as a clock pulse delay, making it tolerant against pulse evaporation under PVT variations and degraded load/slope conditions. The replica latch write pulse delay also tracks actual pulsed latch clk-to-q delay across PVT corners, preventing latch writability issues.

This enables a pulsed latch sequential path which is robust against pulse evaporation while still maintaining a low hold time requirement. This pulsed latch can be used to enable high performance designs for modern microprocessors, discrete graphics, DSPs, and hardware accelerators in laptops, servers and other computing devices, for example.

The above and other advantages will be further apparent in view of the following discussion.

FIG. 1 depicts an example of an interconnect mesh circuit with pulsed latches and repeater buses, according to various embodiments. As mentioned, these interconnect circuits send data from point A to B with a fixed interconnect and repeater delay and, by design, meet the extra hold time required by pulsed latches The circuit 100 includes m paths, including a first path 110 which carries a first bit (Bit 1) and an mth path 120 which carries an mth bit (Bit m). Each path carries one bit of data. Each path begins with a sending pulsed latch, such as the pulsed latches 111 and 121 in the paths 110 and 120, respectively, and ends with a receiving latch, such as the pulsed latches 112 and 132 in the paths 110 and 120, respectively. Each pulsed latch has a clock input denoted by a triangle, a data input d and a data output o. The output o=d when the clock pulse goes high.

Each path further includes n repeaters, where each repeater (buffer) drives a certain length interconnect represented as a resistor-capacitor circuit. For example, the path 110 includes repeater driving interconnect 113, 114 and 115 and the path 120 includes repeater driving interconnect 122, 123 and 124. The repeater driving interconnect 113 includes a buffer 116 and an interconnect represented as resistor-capacitor circuit 117. The interconnect and repeater delay meet the hold time required by the pulsed latches.

FIG. 2 depicts an example of a global pulse generator for a set of distributed latches, according to various embodiments. The pulse generator circuit can be shared globally with one or more latches. The circuit 200 includes a global pulse generator 210 and a set of latches including example latches 220, 230, 240 and 250, where the latch 220 is shown in detail. The global pulse generator receives a clock signal (clk) and outputs a signal nc2 to the latches as a routed clock pulse on a path 201. In FIG. 2 partial circuit for a global pulse generator is shown which includes only a final NAND gate 211 followed by an inverter 212 to represent a general pulse generator.

The latch 220 receives the clock pulse at a local clock inverter 221. An output of the inverter 221 on a path 226 is provided to a transmission gate 222 and a tri-state inverter 223. nc2 can be considered to be a clock pulse (clock) and the output on path 226 the complement or inversion of the clock pulse, e.g., clock-bar. clock and clk-bar are used to control a transmission gate 222 and a tri-state inverter 223 in the latch. The transmission gate may be a solid-state switch which is comprised of a p-type metal-oxide-semiconductor (pMOS) transistor and an n-type metal-oxide-semiconductor (nMOS) transistor, where the control gates are biased in a complementary manner so that both transistors are either on or off.

An inverter 224 receives a data bit “d” at its input and provides a corresponding output as an input to the transmission gate. The input of the transmission gate is passed to the output on a path 227 if the voltage on the path 226 is low (logic 0) and the voltage on the path 225 is high (logic 1). The path 227 is coupled to an input of an inverter 228 whose output on a path 229 is provided as an input to the tri-state inverter 223. The signals on the paths 225 and 226 are primary enable and complementary enable signals, respectively, for the tri-state inverter. The tri-state inverter can be an active low tri-state inverter, for example. In this case, if the primary enable signal is high, the output on the path 227 is high impedance regardless of whether the input is high or low. If the primary enable signal is low and the input on path 229 is low, the output on the path is high. If the primary enable signal is low and the input on path 229 is high, the output on the path is low. A tri-state inverter thus has three possible output states: high impedance, 0 and 1. The output on the path 227 is provided as an input to an inverter 231, whose output is a data bit “o.”

The latches 230, 240 and 250 can be configured similarly to receive a respective input bit and provide a respective output bit. In some cases, multiple latches are arranged sequentially, one after another. Each latch can be used for various purposes in a respective circuit as a sequential logic component.

FIG. 3 depicts an example of a local pulse generator circuit integrated with a multi-bit pulsed latch standard cell circuit, according to various embodiments. This is an example of a single monolithic cell. The circuit 300 includes a local pulse generator 310 and a set of latches including example latches 320, 330 and 340, where the latch 320 is shown in detail. The local pulse generator receives a clock signal (clk) and outputs first and second clock pulses nc1 and nc2, respectively, to the latches on paths 311 and 312, respectively. In FIG. 3, a partial circuit for a local pulse generator is shown which includes only the final NAND gate 313 followed by an inverter 314 to represent a general pulse generator. nc1 is output from a NAND gate 313 and nc2 is output from a following inverter 314. nc1 and nc2 are complementary or inverses of one another, meaning nc2=1 when nc1=0 and nc2=0 when nc1=1. The paths 311 and 312 are first and second paths, respectively, to couple the first and second clock pulses, respectively, to one or more pulsed latches.

The latch 320 receives nc1 and nc2 as complementary enable signals for a transmission gate 322 and a tri-state inverter 323. An inverter 324 receives a data bit “d0” (where “0” denotes the first latch in the set of latches) at its input and provides a corresponding output as an input to the transmission gate. The input of the transmission gate is passed to the output on a path 327 if nc1 is low (logic 0) and nc2 is high (logic 1). The path 327 is coupled to an input of an inverter 328 whose output on a path 329 is provided as an input to the tri-state inverter 323. nc2 and nc1 are primary enable and complementary enable signals, respectively, for the tri-state inverter. If the primary enable signal is high, the output on the path 327 is high impedance regardless of whether the input is high or low. If the primary enable signal is low and the input on path 329 is low, the output on the path 327 is high. If the primary enable signal is low and the input on path 329 is high, the output on the path 327 is low. The output on the path 327 is provided as an input to an inverter 331, whose output is a data bit “00.”

The latches 330 and 340 can be configured similarly to receive a respective input bit and provide a respective output bit.

Note that the clock signal nc2 but not nc1 is provided to the latches by the global pulse generator in FIG. 2, while both the first and second clock signals, nc1 and nc2, respectively, are provided to the latches by the local pulse generator in FIG. 3. Since the latch 320 of FIG. 3 has access to both nc1 and nc2 to control the transmission gate and tri-state inverter, it does not use a local clock inverter 221 such as in FIG. 2.

FIG. 4A depicts an example of a comparative pulse generator circuit, according to various embodiments. The circuit 400 includes a chain of series-connected inverters 401-405 in a first path which provide a delayed input to a NAND gate 410, and a path 406 which provides a non-delayed input to the NAND gate. An output of the NAND gate, nc1, is provided as an input to an inverter 412. An output of the inverter is nc2. The waveform 420 depicts an increasing edge of the clk signal. The waveforms 421 and 422 depict corresponding low and high pulses for nc1 and nc2, respectively. The series of inverters provides a delay which is proportional to the number of inverters. If one or both inputs of the NAND gate are low (0), the output is low. If both inputs of the NAND gate are high (1), the output is high.

nc1 and nc2 are clock signals that can be routed to a set of latches.

FIG. 4B depicts waveforms from the pulse generator circuit of FIG. 4A, where pulse evaporation occurs on nc1 and n2, according to various embodiments. At the NAND gate 410, clk changes from low to high at a time t0, as represented by the rising edge 430. nc1 changes from high to low at 1, as represented by the falling edge 431, after a delay of the NAND gate 410, Tdelay_NAND. nc2 changes from low to high at a time t2, as represented by the rising edge 432, after a delay of the inverter 412, Tdelay_INV. These waveforms indicate the first edge is pushed due to a large NAND/INV (inverter) delay. The waveforms for nc1 and nc2 here depict pulse evaporation, where these waveforms do not reach a respective low or high level, respectively, to form full pulses.

FIG. 5A depicts an example of another comparative pulse generator circuit, according to various embodiments. This circuit 500 includes cross-coupled NAND gates 501 and 502. The clock signal, represented by a waveform 520, is input to a NAND gate 503. Another input to the NAND gate 502 is from a pair of series-connected inverters 504 and 505. An output of the NAND gate, nc1, represented by the waveform 521, is provided to an inverter 512 whose output is nc2, represented by the waveform 522. nc1 is also provided as one input to the NAND gate 501. A second input to the NAND gate 501 is an output of the NAND gate 502. One input of the NAND gate 502 is clk and another input is the output of the NAND gate 501. nc1 is fed back to the cross-coupled NAND gates to create and close the pulse.

nc1 and nc2 are clock signals that can be routed to a set of latches.

FIG. 5B depicts waveforms from the pulse generator circuit of FIG. 5A, where pulse evaporation occurs on nc2, according to various embodiments. At the NAND gate 503, clk changes from low to high at a time to, as represented by the rising edge 530. nc1 changes from high to low at t1, as represented by the falling edge 531, after a delay of the NAND gate 503, Tdelay_NAND. nc2 changes from low to high at a time t2, as represented by the rising edge 532, after a delay of the inverter 512, Tdelay_INV. These waveforms indicate the first edge is pushed due to a large INV (inverter) delay. The waveform for nc2 here depicts pulse evaporation, while the waveform for nc1 is acceptable.

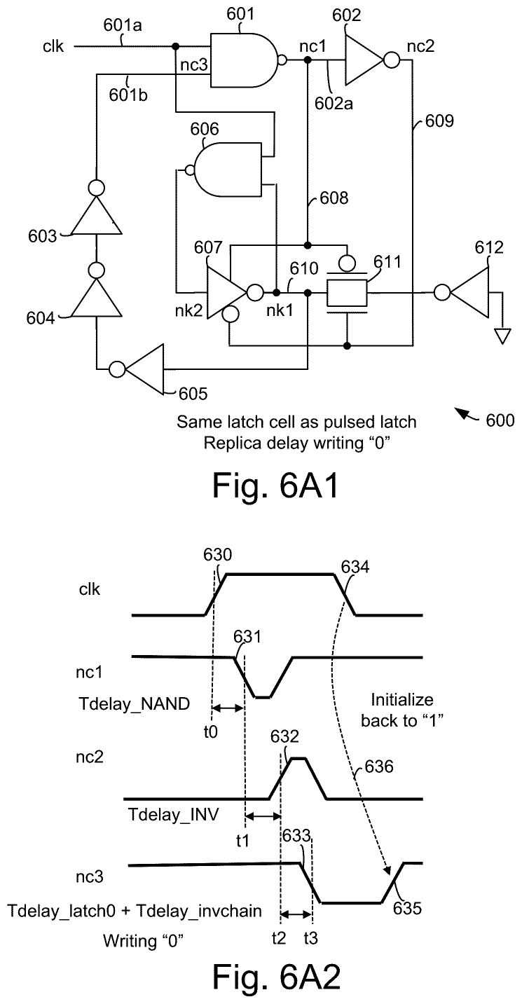

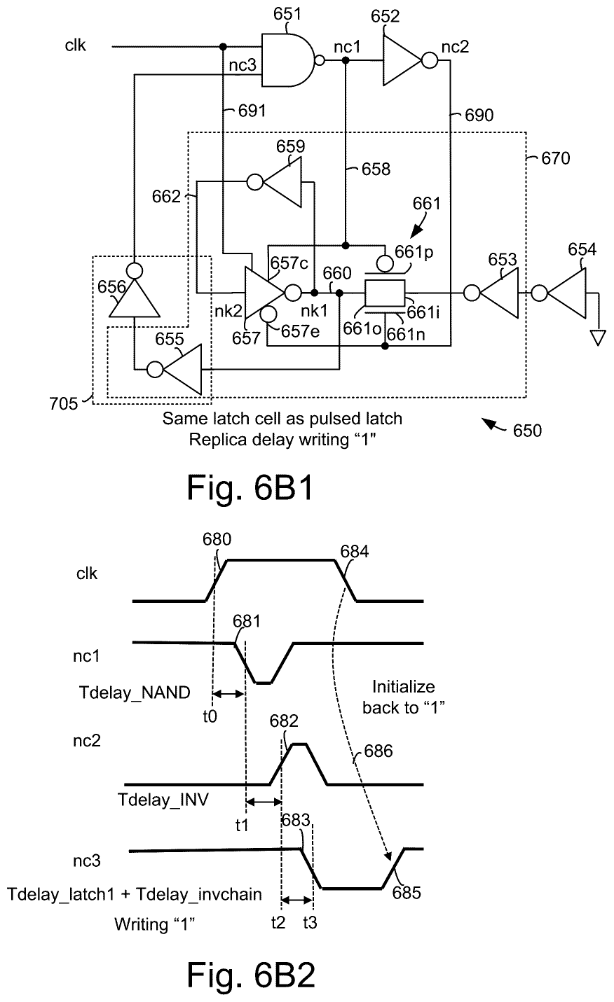

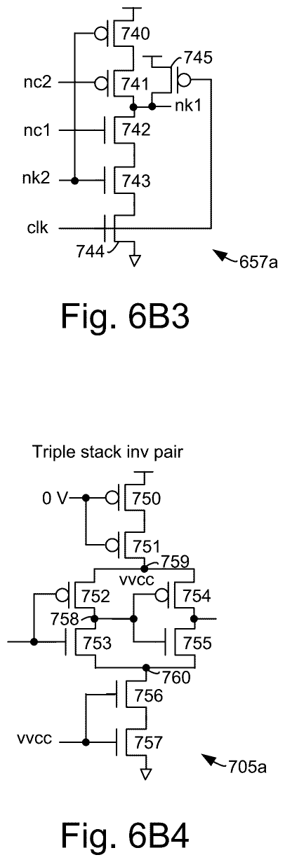

FIG. 6A1 depicts a replica feedback pulse generator circuit with a same latch cell as a pulsed latch with replica delay writing of a “0,” according to various embodiments. An example replica feedback pulse generator circuit 600 is depicted. The clock signal is provided as one input to a NAND gate 601 on a first input path 601a, and a signal nc3 is provided as another input to the NAND gate 601 on a second input path 601b. The output of the NAND gate 601, nc1, on an output path 602a, is provided as an input to an inverter 602, whose output is nc2 on a path 609. The path 602a is also an input path of the inverter 602. nc2 is therefore the complement or inverse of nc1. nc3 on path 601b is provided by a chain of inverters 603, 604 and 605, where nk1 is input to the inverter 605. nc3 is therefore the complement of nk1. clk is also provided to a NAND gate 606 whose output is an input to a tri-state inverter 607. The tri-state inverter is controlled by nc1 on a path 608 and nc2 on the path 609. The output of the tri-state inverter is nk1 on a path 610, which in turn is coupled to the output of a transmission gate 611. An input to the transmission gate is an output of an inverter 612, a logical 1, whose input is coupled to ground.

In this example, the inverter 612 which provides the input of the transmission gate is a single inverter. In some implementations an odd number of inverters are provided in a sequence, e.g., 1, 3, 5, . . . to provide the input of the transmission gate.

The path 609 carries nc2 as a primary enable signal for the tri-state inverter 607 while the path 608 carries nc1 as a complementary enable signal for the tri-state inverter.

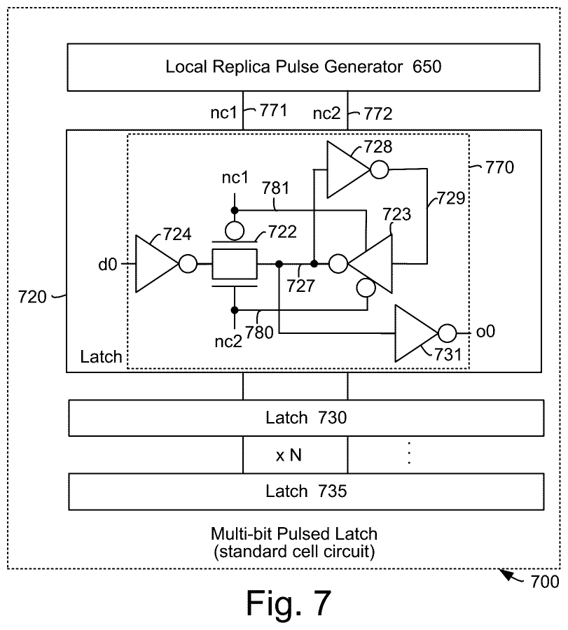

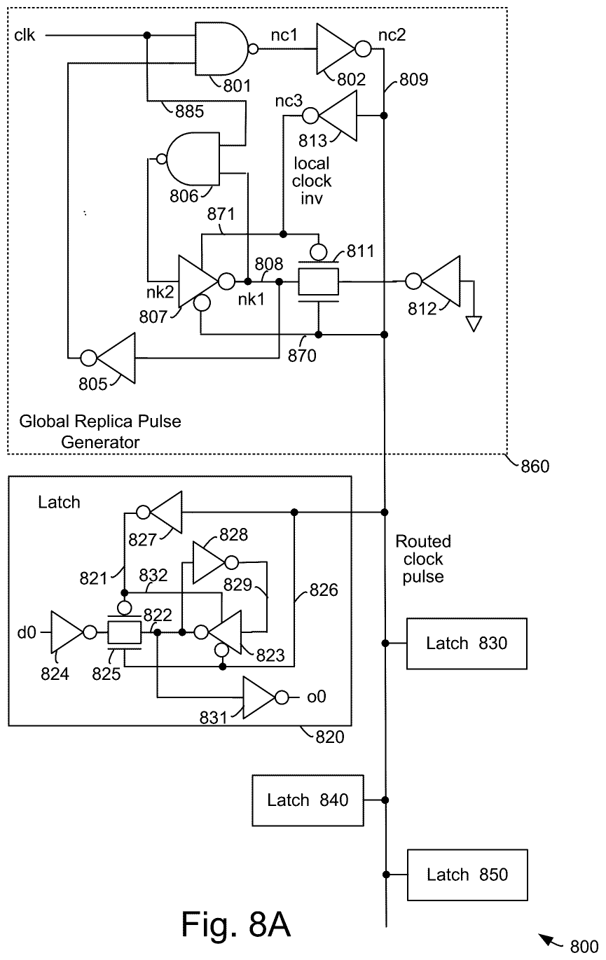

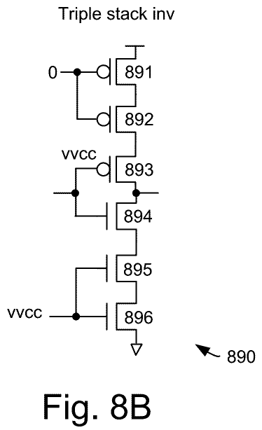

nc1 and nc2 are clock signals that can be routed to a set of latches such as depicted in FIGS. 7 and 8A.

The NAND gate 601 and inverter 602 are examples of one or more logic gates which can be used to provide the clock pulses nc1 and nc2 based on a clock signal, clk.

FIG. 6A2 depicts waveforms consistent with the replica feedback pulse generator circuit of FIG. 6A1, according to various embodiments. At the NAND gate 601, clk changes from low to high at a time to, as represented by the rising edge 630. nc1 changes from high to low at t1, as represented by the falling edge 631, after a delay of the NAND gate 601, Tdelay_NAND. nc2 changes from low to high at a time t2, as represented by the rising edge 632, after a delay of the inverter 602, Tdelay_INV. nc3 changes from high to low at t3, as represented by the falling edge 633, after a delay of Tdelay_latch0+Tdelay_invchain, where Tdelay_latch0 is the delay of a latch comprised by the NAND gate 606, tri-state inverter 607, transmission gate 611, inverter 605 and inverter 612, and Tdelay_invchain is a delay of an inverter chain comprising the inverters 603-604. In this example, the chain of inverters includes a sequence of two inverters. In some implementations an even number of inverters are provided in a sequence, e.g., 0, 2, 4, . . . .

Subsequently, referring to the arrow 636, the decrease in clk, represented by the falling edge 634, results in an increase in nc3, represented by the rising edge 635.

The example circuit 600 feeds back the output nc1 of the NAND gate 601 and the output nc2 of the inverter 602 to the clock devices of a replica latch. The latch is a replica of the pulsed latch driven by this pulse generator. The latch output feeds back nc3, the second input of the NAND gate 601 through the chain of inverters 603-604. The chain of inverters is added to create an additional pulse delay if required to meet latch writability requirements. The replica latch state node (nk2) can be set to “1” when clk=0 through the NAND gate 606 in the cross-coupled keeper. The input of the latch is tied to “0” due to the grounding of the input of the inverter 612. When clk is “0”, nc1 and nc2 are initialized to “1” and “0” respectively. The latch state node nk2 is set to “0,” keeping the second input (nc3) of the clocked NAND gate 601 at “1.”

As shown in FIG. 6A2, when clk transitions from “0” to “1,” nc1 and nc2 transition from “1” to “0” and “0” to “1,” respectively. nc1=1 since the output of a NAND gate=1 if one or both inputs=0. nc2=0 since it is the complement of nc1. These falling/rising edge transitions on nc1/nc2 write “0” to the latch state node nk2 followed by a falling edge transition on the input (nc3) of the clocked NAND gate 601. nk2=0 since it is the output of the NAND gate 606, where clk=1 is one of the inputs and nk1=1 is the other input. nk1=1 since a 1 is passed from the inverter 612 through the transmission gate 611 to the path 610. Moreover, with nc1=0, the tri-state inverter is disabled so that has a high impedance output. The falling edge on nc3 pulls nc1 and nc2 back to “1” and “0,” respectively, completing the pulse generation. Finally, when clk goes from “1” to “0,” nc1 and nc2 remain at “1” and “0,” respectively, forced by clk being “0.” The nk2 node is set back to “1” which initializes nc3 back to “1.” The pulse delay width generated by the circuit advantageously tracks the latch clk-to-q delay for writing “0” across PVT.

The circuit 600 writes 0 to the node nc3 when clk goes high.

FIG. 6B1 depicts a replica feedback pulse generator circuit with a same latch cell as a pulsed latch with replica delay writing of a “1,” according to various embodiments. An example replica feedback pulse generator circuit 650 is depicted. The clock signal is provided as one input to a NAND gate 651, and a signal nc3 is provided as another input to the NAND gate 651. The output of the NAND gate 651, nc1, is provided as an input to an inverter 652, whose output is nc2 on a path 690. nc2 is therefore the complement of nc1. nc3 is provided by an inverter 656. The input of the inverter 656 is provided by another inverter 655, where nk1 is input to the inverter 655. nc3 is therefore equal to nk1. In this example, only one inverter 656 is provided. In some implementations an odd number of inverters are provided in a sequence, e.g., 1, 3, 5, . . . .

clk is also provided on a path 691 to a modified tri-state inverter 657 with an output which is forced to “1” when clk is “0” (see FIG. 6B3). The modified tri-state inverter is controlled by nc1, nc2 and clk. The output of the tri-state inverter is nk1 on a path 660, which in turn is coupled to the output of a transmission gate 661 and to the input of an inverter 659. The output of the inverter 659 on a path 662 is fed back as an input to the modified tri-state inverter 657. An input to the transmission gate is an output of a chain of inverters 653 and 654, where an input of the inverter 654 is coupled to ground. The chain of inverters 653 and 654 thus output a logic 0 to the input 661i of the transmission gate.

The modified tri-state inverter 657, transmission gate 661 and inverters 653, 655 and 659 are latch components which make up a delay circuit 670 which replicates a delay of corresponding latch components, e.g., 770 in FIG. 7. The term replicate or the like refers to an approximate replication within a specified+−/ tolerance such as up to, e.g., +/−20% of a latch delay. The delay circuit 670 includes latch components which are a match to the latch components 770 of the latch 720 in FIG. 7, for example. The inverters 653, 659 and 655 are first, second and third inverters, respectively.

The path 690 carries nc2 as a primary enable signal for the modified tri-state inverter 657 while the path 658 carries nc1 as a complementary enable signal for the modified tri-state inverter. The modified tri-state inverter has a primary enable input 657e which receives the primary enable signal and a complementary enable input 657c which receives the complementary enable signal.

nc1 and nc2 are clock signals that can be routed to a set of latches such as depicted in FIGS. 7 and 8A.

The circuit 650 further includes a pair of inverters 705 comprising the inverters 655 and 656, for example. See FIG. 6B4 for an example implementation.

FIG. 6B2 depicts waveforms consistent with the replica feedback pulse generator circuit of FIG. 6A1, according to various embodiments. At the NAND gate 651, clk changes from low to high at a time t0, as represented by the rising edge 680. nc1 changes from high to low at t1, as represented by the falling edge 681, after a delay of the NAND gate 651, Tdelay_NAND. nc2 changes from low to high at a time t2, as represented by the rising edge 682, after a delay of the inverter 652, Tdelay_INV. nc3 changes from high to low at t3, as represented by the falling edge 683, after a delay of Tdelay_latch1+Tdelay_invchain, where Tdelay_latch1 is the delay of a latch comprised by the inverter 659, modified tri-state inverter 657, transmission gate 661 and inverters 653 and 655, and Tdelay_invchain is a delay of the inverter 656.

A transmission gate generally comprises a source, which is the input, a drain, which is the output, a p-gate (represented by a plate with a circle) and an n-gate (represented by a plate without a circle). For example, the transmission gate 661 has an input 661i, an output 6610, a p-gate 661p and an n-gate 661n. The values at the n-gate and the p-gate are expected to be complementary, e.g., opposite to each other. If the p-gate is 0 (low) while n-gate is 1 (high), then the value at the source is transmitted to the drain. If the p-gate is 1 while the p-gate is 0, then the connection between the input and output is broken, so the voltage at the drain is left floating.

Subsequently, referring to the arrow 686, the decrease in clk, represented by the falling edge 684, results in an increase in nc3, represented by the rising edge 685.

FIG. 6B1 thus shows another version of replica feed-back pulse generator circuit which generates a pulse delay width which tracks latch clk-2-q delay for writing “1.” Since the replica feedback pulse generator feeds back both the output nc1 of the NAND gate 651 and the output nc2 of the inverter 652 to create a pulse delay, it does not have diverged paths between the first and second edges of the pulse, making it tolerant to pulse evaporation under PVT variation and degraded load/slope conditions. The same applies to FIG. 6A1.

FIG. 6B3 depicts a circuit 657a which is an example implementation of the modified tri-state inverter 657 of FIG. 6B1, according to various embodiments. An output of the tri-state inverter is forced to “1” when clk is “0′.” In particular, an nMOS transistor 744 and a pMOS transistor 745 which are connected or coupled to the clock signal (clk) are added to the tri-state inverter to force the output of the tri-state inverter to “1” when clk is “0”.

The circuit includes two pMOS transistors 740 and 741 in series with three nMOS transistors 742, 743 and 744. An additional pMOS transistor 745 has its drain coupled to a point between the transistors 741 and 742, e.g., to the drain of the pMOS transistor 741 and the drain of the nMOS transistor 742. nc2 is provided to the control gate of the pMOS transistor 741. nc1 is provided to the control gate of the nMOS transistor 742. nk2 is provided to the control gates of the pMOS transistor 740 and the nMOS transistor 743. clk is provided to the control gates of the nMOS transistor 744 and the pMOS transistor 745. A drain of the pMOS transistor 740 is coupled to a power supply voltage and a source of the nMOS transistor 744 is coupled to ground.

FIG. 6B4 depicts a triple stack inverter pair circuit 705a which is an example implementation of the pair of inverters 705 of FIG. 6B1, according to various embodiments. A pair of pMOS transistors 750 and 751 in series receive 0 V at their control gate to provide them in a conductive state. Two pairs of transistors are coupled to the pMOS transistor 751 at a node 759. A first pair includes a pMOS transistor 752 and an nMOS transistor 753 which have their control gates coupled to one another. A second pair includes a pMOS transistor 754 and an nMOS transistor 755 which have their control gate coupled to one another and to a point which is between the transistors 752 and 753. These two pairs of transistors are also coupled to a pair of nMOS transistors 756 and 757 in series at a node 760. These nMOS transistors have their control gates coupled to one another and receive a voltage vvcc. This voltage is also provided at the node 759. the control gates of the transistors 754 and 755 are coupled to a node 758 which is between the transistors 752 and 753.

FIG. 7 depicts an example local replica feedback pulse generator integrated with a multi-bit pulsed latch standard cell circuit, according to various embodiments. The circuit 700 includes the local replica pulse generator 650 of FIG. 6B and latches 720, 730 and 735, where the example latch 720 is shown in detail.

The latch 720 receives nc1 and nc2 as complementary enable signals for a transmission gate 722 and a tri-state inverter 723. An input inverter 724 receives a data bit “do” at its input and provides a corresponding output as an input to the transmission gate. The input of the transmission gate is passed to the output on a path 727 if nc1 is low (logic 0) and nc2 is high (logic 1). The path 727 is coupled to an input of an inverter 728 whose output on a path 729 is provided as an input to the tri-state inverter 723. nc2 and nc1 are primary enable and complementary enable signals, respectively, for the tri-state inverter. If the enable signal is high, the output on the path 727 is high impedance regardless of whether the input is high or low. If the enable signal is low and the input on path 729 is low, the output on the path 727 is high. If the enable signal is low and the input on path 729 is high, the output on the path 727 is low. The output on the path 727 is provided as an input to an output inverter 731, whose output is a data bit “o0.”

The path 780 carries nc2 as the primary enable signal for the tri-state inverter 723 while the path 781 carries nc1 as the complementary enable signal for the tri-state inverter.

The latches 730 and 735 can be configured similarly to receive a respective input bit and provide a respective output bit.

The paths 771 and 772 are first and second paths, respectively, to couple the first and second clock pulses, nc1 and nc2, respectively, to one or more pulsed latches.

In the latch topology of the pulse generator 650, the delay for writing “1” is greater than the delay for writing “0.” Accordingly, to accommodate the longer delay, the replica feedback latch for writing “1” can be implemented. Both the replica and the multi-bit latch are driven internally by generated pulse clocks nc1 and nc2. Since nc1 and nc2 are local to the standard cell circuit, the load/slope on nc1/nc2 are fixed and depends on pulse generator sizing and size (N) of the multi-bit latch. The inverter pairs (e.g., inverters 655 and 656) added to create additional pulse delay can be triple stacked with always-on transistors. This results in a larger fan-out delay and reduces variation impact on pulse evaporation with a minimum impact on clock switching capacitance/clock power.

Vmin circuit simulations were performed for (1) the comparative pulse generator of FIG. 4A, (2) the another comparative pulse generator of FIG. 5A, and (3) the local replica pulse generator of FIG. 7. The simulations involved each pulse generator feeding eight-bit pulsed latches as local pulse generator, at all the process corners, including different sigma values, temperatures and input clock slopes. The inverter pairs added to create additional pulse delay in both cases (1) and (2) are triple stacked as in the replica feedback pulse generator of case (3). For an iso pulse-width designs, the replica pulse generator circuit of case (3) results in 150 mV-350 mV/150 mV-200 mV better (lower) Vmin across a range of input clock slopes compared to cases (1) and (2). Although energy consumption is increased somewhat for case (3), it is an acceptable tradeoff for advantages including greater tolerance against pulse evaporation and degraded load/slope conditions and the avoidance of latch writability issues.

Iso-energy circuits can be implemented by adding two extra delay inverters in cases (1) and (2) to increase their pulse width at the cost of an extra hold time requirement compared to the replica pulse generator design of case (3). At iso-energy design, the replica pulse generator circuit shows 100 mV-150 mV/100 mV-100 mV better Vmin across a range of input clock slopes, compared to case (1) with seven inverters or case (2) with four inverters.

FIG. 8A depicts a global replica feedback pulse generator with a generated clock pulse nc2 routed to multiple pulsed latches, according to various embodiments. The circuit 800 includes the pulse generator 860 and latches 820, 830, 840 and 850, where the latch 820 is shown in detail. In the pulse generator, the clock signal clk is provided as one input to a NAND gate 801, and a signal output from an inverter 805 is provided as another input to the NAND gate 801. In this example, a single inverter 805 is provided. In some implementations, an odd number of inverters are provided in a sequence.

The output of the NAND gate, nc1, is provided as an input to an inverter 802, whose output is nc2 on a path 809. The path 809 is used to output the clock pulse nc2 to one or more pulsed latches. For example, nc2 is routed as a clock pulse to the latches 820, 830, 840 and 850.

The path 870 carries nc2 as a primary enable signal for the tri-state inverter 807 while the path 871 carries nc3 as a complementary enable signal for the tri-state inverter.

nc3 is output by an inverter 813 which receives nc2 as its input. clk is also provided on a path 885 to a NAND gate 806, where another input to the NAND gate 806 is nk1 on a path 808. A tri-state inverter 807 is controlled by nc2 and nc3. The output of the tri-state inverter is nk1 on the path 808, which in turn is coupled to the output of the transmission gate 811. An input to the transmission gate is an output of an inverter 812 having an input coupled to ground. nk1 is further input to the inverter 805

The latch 820 receives nc2 at an inverter 827, which provides an output on a path 821 as a complementary enable signal for a transmission gate 825 and a tri-state inverter 823. nc2 on the path 826 is a primary enable signal. An inverter 824 receives a data bit “d0” at its input and provides a corresponding output as an input to the transmission gate. The input of the transmission gate is passed to the output on a path 822 if the signal on path 821 is low (logic 0) and nc2 is high (logic 1). The path 822 is coupled to an input of the inverter 828 whose output on a path 829 is provided as an input to the tri-state inverter 823. If the enable signal is high, the output on the path 822 is high impedance regardless of whether the input is high or low. If the enable signal is low and the input on path 829 is low, the output on the path 822 is high. If the enable signal is low and the input on path 829 is high, the output on the path 822 is low. The output on the path 822 is provided as an input to an inverter 831, whose output is a data bit “00.”

The path 826 carries nc2 as a primary enable signal for the tri-state inverter 823 while the path 832 carries the complement of nc2, or nc2-bar, as a complementary enable signal for the tri-state inverter.

The latches 830, 840 and 850 can be configured similarly to receive a respective input bit and provide a respective output bit.

FIG. 8A thus shows an example circuit implementation of a global replica feedback pulse generator 860 with a generated pulse clock nc2 which is routed to multiple pulsed latches 820, 830, 840 and 850. A local clock inverter 813 in the replica latch mimics the external latch local clock inverter (e.g., inverter 827). Moreover, since, for this latch topology, the delay in writing a “0” is longer than the delay in writing a “1,” the replica feedback latch with writing “0” is implemented to accommodate the longer delay. Both the replica and the external pulsed latches are driven by the generated pulse clocks nc2. In this topology, a feedback delay originates from nc2, making it tolerant against pulse evaporation under PVT variations and degraded load/slope conditions at nc2. The load/slope on nc2 depends on the pulse generator sizing and the external load due to multiple pulsed latch connections. The other diverged nodes nc1/nc3 have fixed small local-loads/slopes and hence have less effect on pulse evaporation and Vmin. The inverter 805 as well as the local clock inverter 813, can be triple stacked with always-on transistors for larger fan-out delay and to reduce variation impact on pulse evaporation with a minimum impact on clock switching capacitance/clock power.

Vmin circuit simulations were performed for (1) the comparative pulse generator of FIG. 4A, (2) the another comparative pulse generator of FIG. 5A, and (3) the replica pulse generator of FIG. 8A. The simulations involved each pulse generator feeding multiple pulsed latches as global pulse generator at all the process corners using different sigma values, temperatures, input clock slopes and output clock (nc2) slopes. At an nc2 slope of a value S, the replica pulse generator shows a Vmin which is 100 mV-150 mV lower compared to case (1) with five inverters and case (2) with two inverters, similar to case (1) with seven inverters and case (2) with four inverters. Additionally, at an nc2 slope condition of 2×S, case (1) with five inverters and case (2) with two inverters fail to work. The Vmin with the replica pulse generator circuit remains at a low level and shows a 150 mV-150 mV/150 mV-250V better Vmin across a range of input clock slopes, compared to the iso-energy case (1) with seven inverters and case (2) with four inverters.

FIG. 8B depicts a triple stack inverter circuit which is an example implementation of the inverters 805 and 813 of FIG. 8A, according to various embodiments. The circuit 890 includes a set of series-connected transistors 891-896. The set includes pMOS transistors 891 and 892 whose control gates are connected, a pMOS transistor 893 and an nMOS transistor 894 whose control gates are connected and receive a voltage vvcc, and nMOS transistors 895 and 896 whose control gates are connected and receive vvcc. Each instance of the circuit 890 represents one of the inverters 805 or 813.

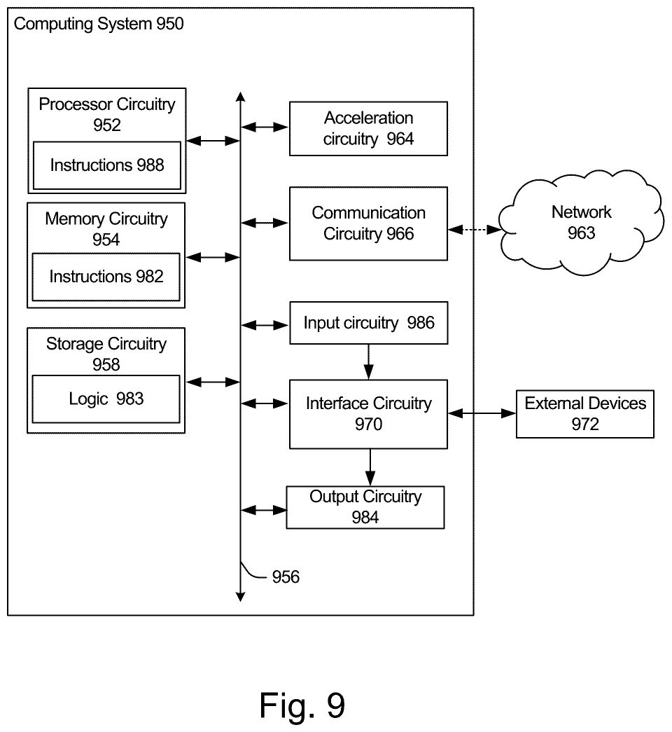

FIG. 9 illustrates an example of components that may be present in a computing system 950 for implementing the techniques (e.g., operations, processes, methods, and methodologies) described herein. The memory circuitry 954 may store instructions and the processor circuitry 952 may execute the instructions to perform the functions described herein. The pulse generator and pulsed latches described herein can be in any of the components of the computing system, the external devices or the network.

The computing system 950 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 950, or as components otherwise incorporated within a chassis of a larger system. For one embodiment, at least one processor 952 may be packaged together with computational logic 982 and configured to practice aspects of various example embodiments described herein to form a System in Package (SiP) or a System on Chip (SoC).

The system 950 includes processor circuitry in the form of one or more processors 952. The processor circuitry 952 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 952 may include one or more hardware accelerators (e.g., same or similar to acceleration circuitry 964), which may be microprocessors, programmable processing devices (e.g., FPGA, ASIC, etc.), or the like. The one or more accelerators may include, for example, computer vision and/or deep learning accelerators. In some implementations, the processor circuitry 952 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 952 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low voltage processor, an embedded processor, or any other known processing elements, or any suitable combination thereof. The processors (or cores) 952 may be coupled with or may include memory/storage and may be configured to execute instructions stored in the memory/storage to enable various applications or operating systems to run on the platform 950. The processors (or cores) 952 is configured to operate application software to provide a specific service to a user of the platform 950. In some embodiments, the processor(s) 952 may be a special-purpose processor(s)/controller(s) configured (or configurable) to operate according to the various embodiments herein.

As examples, the processor(s) 952 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 952 may be a part of a system on a chip (SoC), System-in-Package (SiP), a multi-chip package (MCP), and/or the like, in which the processor(s) 952 and other components are formed into a single integrated circuit, or a single package, such as the Edison™ or Galileo™ SoC boards from Intel® Corporation. Other examples of the processor(s) 952 are mentioned elsewhere in the present disclosure.

The system 950 may include or be coupled to acceleration circuitry 964, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 964 may comprise logic blocks or logic fabric and other interconnected resources that may be programmed (configured) to perform various functions, such as the procedures, methods, functions, etc. of the various embodiments discussed herein. In such implementations, the acceleration circuitry 964 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 952 and/or acceleration circuitry 964 may include hardware elements specifically tailored for machine learning and/or artificial intelligence (AI) functionality. In these implementations, the processor circuitry 952 and/or acceleration circuitry 964 may be, or may include, an AI engine chip that can run many different kinds of AI instruction sets once loaded with the appropriate weightings and training code. Additionally or alternatively, the processor circuitry 952 and/or acceleration circuitry 964 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPS™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 952 and/or acceleration circuitry 964 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin 970 provided by Huawei®, and/or the like. In some hardware-based implementations, individual subsystems of system 950 may be operated by the respective AI accelerating co-processor(s), AI GPUs, TPUs, or hardware accelerators (e.g., FPGAS, ASICs, DSPs, SoCs, etc.), etc., that are configured with appropriate logic blocks, bit stream(s), etc. to perform their respective functions.

The system 950 also includes system memory 954. Any number of memory devices may be used to provide for a given amount of system memory. As examples, the memory 954 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 954 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 954 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 958 provides persistent storage of information such as data, applications, operating systems and so forth. In an example, the storage 958 may be implemented via a solid-state disk drive (SSDD) and/or high-speed electrically erasable memory (commonly referred to as “flash memory”). Other devices that may be used for the storage 958 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 954 and/or storage circuitry 958 may also incorporate three-dimensional (3D) cross-point (XPOINT) memories from Intel® and Micron®.

The memory circuitry 954 and/or storage circuitry 958 is/are configured to store computational logic 983 in the form of software, firmware, microcode, or hardware-level instructions to implement the techniques described herein. The computational logic 983 may be employed to store working copies and/or permanent copies of programming instructions, or data to create the programming instructions, for the operation of various components of system 950 (e.g., drivers, libraries, application programming interfaces (APIs), etc.), an operating system of system 950, one or more applications, and/or for carrying out the embodiments discussed herein. The computational logic 983 may be stored or loaded into memory circuitry 954 as instructions 982, or data to create the instructions 982, which are then accessed for execution by the processor circuitry 952 to carry out the functions described herein. The processor circuitry 952 and/or the acceleration circuitry 964 accesses the memory circuitry 954 and/or the storage circuitry 958 over the interconnect (IX) 956. The instructions 982 direct the processor circuitry 952 to perform a specific sequence or flow of actions, for example, as described with respect to flowchart(s) and block diagram(s) of operations and functionality depicted previously. The various elements may be implemented by assembler instructions supported by processor circuitry 952 or high-level languages that may be compiled into instructions 988, or data to create the instructions 988, to be executed by the processor circuitry 952. The permanent copy of the programming instructions may be placed into persistent storage devices of storage circuitry 958 in the factory or in the field through, for example, a distribution medium (not shown), through a communication interface (e.g., from a distribution server (not shown)), over-the-air (OTA), or any combination thereof.

The IX 956 couples the processor 952 to communication circuitry 966 for communications with other devices, such as a remote server (not shown) and the like. The communication circuitry 966 is a hardware element, or collection of hardware elements, used to communicate over one or more networks 963 and/or with other devices. In one example, communication circuitry 966 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 966 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 956 also couples the processor 952 to interface circuitry 970 that is used to connect system 950 with one or more external devices 972. The external devices 972 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 950, which are referred to as input circuitry 986 and output circuitry 984. The input circuitry 986 and output circuitry 984 include one or more user interfaces designed to enable user interaction with the platform 950 and/or peripheral component interfaces designed to enable peripheral component interaction with the platform 950. Input circuitry 986 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 984 may be included to show information or otherwise convey information, such as sensor readings, actuator position(s), or other like information. Data and/or graphics may be displayed on one or more user interface components of the output circuitry 984. Output circuitry 984 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 950. The output circuitry 984 may also include speakers and/or other audio emitting devices, printer(s), and/or the like. Additionally or alternatively, sensor(s) may be used as the input circuitry 984 (e.g., an image capture device, motion capture device, or the like) and one or more actuators may be used as the output device circuitry 984 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 950 may communicate over the IX 956. The IX 956 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 956 may be a proprietary bus, for example, used in a SoC based system.

The number, capability, and/or capacity of the elements of system 950 may vary, depending on whether computing system 950 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 950 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.

Example 1 includes an apparatus, comprising: one or more logic gates comprising a first input and a second input, wherein the first input is to receive a clock signal, and the one or more logic gates are to output a first clock pulse and a second clock pulse which is an inverse of the first clock pulse; a first path and a second path coupled to the one or more logic gates, wherein the first path is to couple the first clock pulse to one or more pulsed latches and the second path is to couple the second clock pulse to the one or more pulsed latches; and latch components of the pulse generator which are to replicate a delay of latch components in the one or more pulsed latches, wherein the latch components of the pulse generator are to provide an output to the second input of the one or more logic gates.

Example 2 includes the pulse generator of Example 1, wherein: the one or more logic gates comprise a NAND gate and an inverter; the NAND gate comprises the first input and the second input; the NAND gate is to output the first clock pulse; and the inverter receives the first clock pulse from the NAND gate and is to output the second clock pulse.

Example 3 includes the pulse generator of Example 1 or 2, wherein the latch components of the pulse generator are to write a logic 1 to the second input of the one or more logic gates when the clock signal goes high.

Example 4 includes the pulse generator of any one of Examples 1-3, wherein: the latch components of the pulse generator comprise a tri-state inverter, a transmission gate, and first, second and third inverters; an output of the first inverter is coupled to the transmission gate; an output of the tri-state inverter is coupled to the transmission gate and to an input of the second inverter; an output of the second inverter is coupled to an input of the tri-state inverter; and the output of the tri-state inverter is coupled to an input of the third inverter.

Example 5 includes the pulse generator of Example 4, further comprising: a path to couple the second clock pulse to a primary enable input of the tri-state inverter; and a path to couple the first clock pulse to a complementary enable input of the tri-state inverter.

Example 6 includes the pulse generator of Example 4 or 5, further comprising a path to couple the clock signal to the tri-state inverter, wherein an output of the tri-state inverter is 1 when the clock signal is 0.

Example 7 includes the pulse generator of any one of Examples 4-6, further comprising an even number of inverters in a chain to provide a logic 0 to an input of the transmission gate, wherein the chain includes the first inverter.

Example 8 includes the pulse generator of any one of Examples 4-7, further comprising a path to couple the first clock pulse to a p-gate of the transmission gate.

Example 9 includes the pulse generator of any one of Examples 4-8, further comprising an even number of inverters in a chain to couple an output of the tri-state inverter to the second input of the one or more logic gates, wherein the chain includes the third inverter.

Example 10 includes an apparatus, comprising: a pulse generator to receive a clock signal, and in response to the clock signal, to output a first clock pulse and a second clock pulse which is an inverse of the first clock pulse, wherein the pulse generator comprises a delay circuit to delay the first clock pulse relative to the clock signal; and a pulsed latched coupled to the pulse generator, wherein the pulsed latch comprises an input inverter to receive an input bit, latch components which are responsive to the first clock pulse and the second clock pulse, and an output inverter to output an output bit, and the delay circuit replicates a delay of the latch components.

Example 11 includes the apparatus of Example 10, wherein: the latch components of the pulsed latch comprise a tri-state inverter, a transmission gate and an inverter; an output of the tri-state inverter is coupled to the transmission gate and to an input of the inverter; and an output of the inverter is coupled to an input of the tri-state inverter.

Example 12 includes the apparatus of Example 11, wherein: the first clock pulse is coupled to a complementary enable input of the tri-state inverter; and the second clock pulse is coupled to a primary enable input of the tri-state inverter.

Example 13 includes the apparatus of Example 11 or 12, wherein: the first clock pulse is coupled to a p-gate of the transmission gate; and the second clock pulse is coupled to an n-gate of the transmission gate.

Example 14 includes the apparatus of any one of Examples 11-13, wherein: the delay circuit comprises a tri-state inverter, a transmission gate and an inverter; and in the delay circuit, an output of the tri-state inverter is coupled to the transmission gate and to an input of the inverter, and an output of the inverter is coupled to an input of the tri-state inverter.

Example 15 includes the apparatus of Example 14, wherein: in the latch components of the pulsed latch: the first clock pulse is coupled to a complementary enable input of the tri-state inverter; and the second clock pulse is coupled to a primary enable input of the tri-state inverter; and in the delay circuit: the first clock pulse is coupled to a complementary enable input of the tri-state inverter; and the second clock pulse is coupled to a primary enable input of the tri-state inverter.

Example 16 includes the apparatus of Example 14 or 15, wherein: in the latch components of the pulsed latch: the first clock pulse is coupled to a p-gate of the transmission gate; and the second clock pulse is coupled to an n-gate of the transmission gate; and in the delay circuit: the first clock pulse is coupled to a p-gate of the transmission gate; and the second clock pulse is coupled to an n-gate of the transmission gate.

Example 17 includes a pulse generator, comprising: a NAND gate comprising a first input and a second input, wherein the first input is to receive a clock signal and to output a first clock pulse; an inverter coupled to the NAND gate, the inverter is to receive the first clock pulse and to output a second clock pulse which is an inverse of the first clock pulse; and a delay circuit responsive to the first clock pulse and the second clock pulse to provide an output to the second input of the NAND gate, to delay the first clock pulse relative to the clock signal.

Example 18 includes the pulse generator of Example 17, wherein: the delay circuit comprises a tri-state inverter, a transmission gate and an inverter; an output of the tri-state inverter is coupled to the transmission gate and to an input of the inverter; an output of the inverter is coupled to an input of the tri-state inverter; the first clock pulse is coupled to a complementary enable input of the tri-state inverter; the second clock pulse is coupled to a primary enable input of the tri-state inverter; the first clock pulse is coupled to a p-gate of the transmission gate; and the second clock pulse is coupled to an n-gate of the transmission gate.

Example 19 includes the pulse generator of Example 18, further comprising an even number of inverters in a chain to couple an output of the tri-state inverter to the second input of the NAND gate, the chain delays the first clock pulse relative to the clock signal.

Example 20 includes the pulse generator of any one of Examples 17-19, wherein the delay circuit is to write a logic 1 to the second input of the NAND gate when the clock signal goes high.

In the present detailed description, reference is made to the accompanying drawings that form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. A pulse generator, comprising:
one or more logic gates comprising a first input and a second input, wherein the first input is to receive a clock signal, and the one or more logic gates are to output a first clock pulse and a second clock pulse which is an inverse of the first clock pulse;
a first path and a second path coupled to the one or more logic gates, wherein the first path is to couple the first clock pulse to one or more pulsed latches and the second path is to couple the second clock pulse to the one or more pulsed latches; and
latch components of the pulse generator which are to replicate a delay of latch components in the one or more pulsed latches, wherein the latch components of the pulse generator are to provide an output to the second input of the one or more logic gates.

2. The pulse generator of claim 1, wherein:
the one or more logic gates comprise a NAND gate and an inverter;
the NAND gate comprises the first input and the second input;
the NAND gate is to output the first clock pulse; and
the inverter receives the first clock pulse from the NAND gate and is to output the second clock pulse.

3. The pulse generator of claim 1, wherein the latch components of the pulse generator are to write a logic 1 to the second input of the one or more logic gates when the clock signal goes high.

4. The pulse generator of claim 1, wherein:
the latch components of the pulse generator comprise a tri-state inverter, a transmission gate, and first, second and third inverters;
an output of the first inverter is coupled to the transmission gate;
an output of the tri-state inverter is coupled to the transmission gate and to an input of the second inverter;
an output of the second inverter is coupled to an input of the tri-state inverter; and
the output of the tri-state inverter is coupled to an input of the third inverter.

5. The pulse generator of claim 4, further comprising:
a path to couple the second clock pulse to a primary enable input of the tri-state inverter; and
a path to couple the first clock pulse to a complementary enable input of the tri-state inverter.

6. The pulse generator of claim 4, further comprising a path to couple the clock signal to the tri-state inverter, wherein an output of the tri-state inverter is 1 when the clock signal is 0.

7. The pulse generator of claim 4, further comprising an even number of inverters in a chain to provide a logic 0 to an input of the transmission gate, wherein the chain includes the first inverter.

8. The pulse generator of claim 4, further comprising a path to couple the first clock pulse to a p-gate of the transmission gate.

9. The pulse generator of claim 4, further comprising an even number of inverters in a chain to couple an output of the tri-state inverter to the second input of the one or more logic gates, wherein the chain includes the third inverter.

10. An apparatus, comprising:
a pulse generator to receive a clock signal, and in response to the clock signal, to output a first clock pulse and a second clock pulse which is an inverse of the first clock pulse, wherein the pulse generator comprises a delay circuit to delay the first clock pulse relative to the clock signal; and
a pulsed latched coupled to the pulse generator, wherein the pulsed latch comprises an input inverter to receive an input bit, latch components which are responsive to the first clock pulse and the second clock pulse, and an output inverter to output an output bit, and the delay circuit replicates a delay of the latch components.

11. The apparatus of claim 10, wherein:
the latch components of the pulsed latch comprise a tri-state inverter, a transmission gate and an inverter;
an output of the tri-state inverter is coupled to the transmission gate and to an input of the inverter; and
an output of the inverter is coupled to an input of the tri-state inverter.

12. The apparatus of claim 11, wherein:
the first clock pulse is coupled to a complementary enable input of the tri-state inverter; and
the second clock pulse is coupled to a primary enable input of the tri-state inverter.

13. The apparatus of claim 11, wherein:
the first clock pulse is coupled to a p-gate of the transmission gate; and
the second clock pulse is coupled to an n-gate of the transmission gate.

14. The apparatus of claim 11, wherein:
the delay circuit comprises a tri-state inverter, a transmission gate and an inverter; and
in the delay circuit, an output of the tri-state inverter is coupled to the transmission gate and to an input of the inverter, and an output of the inverter is coupled to an input of the tri-state inverter.

15. The apparatus of claim 14, wherein:
in the latch components of the pulsed latch:
the first clock pulse is coupled to a complementary enable input of the tri-state inverter; and
the second clock pulse is coupled to a primary enable input of the tri-state inverter; and
in the delay circuit:
the first clock pulse is coupled to a complementary enable input of the tri-state inverter; and
the second clock pulse is coupled to a primary enable input of the tri-state inverter.

16. The apparatus of claim 14, wherein:
in the latch components of the pulsed latch:
the first clock pulse is coupled to a p-gate of the transmission gate; and
the second clock pulse is coupled to an n-gate of the transmission gate; and
in the delay circuit:
the first clock pulse is coupled to a p-gate of the transmission gate; and
the second clock pulse is coupled to an n-gate of the transmission gate.

17. A pulse generator, comprising:
a NAND gate comprising a first input and a second input, wherein the first input is to receive a clock signal and to output a first clock pulse;
an inverter coupled to the NAND gate, the inverter is to receive the first clock pulse and to output a second clock pulse which is an inverse of the first clock pulse; and
a delay circuit responsive to the first clock pulse and the second clock pulse to provide an output to the second input of the NAND gate, to delay the first clock pulse relative to the clock signal.

18. The pulse generator of claim 17, wherein:
the delay circuit comprises a tri-state inverter, a transmission gate and an inverter;
an output of the tri-state inverter is coupled to the transmission gate and to an input of the inverter;
an output of the inverter is coupled to an input of the tri-state inverter;
the first clock pulse is coupled to a complementary enable input of the tri-state inverter;
the second clock pulse is coupled to a primary enable input of the tri-state inverter;
the first clock pulse is coupled to a p-gate of the transmission gate; and
the second clock pulse is coupled to an n-gate of the transmission gate.

19. The pulse generator of claim 18, further comprising an even number of inverters in a chain to couple an output of the tri-state inverter to the second input of the NAND gate, the chain delays the first clock pulse relative to the clock signal.

20. The pulse generator of claim 17, wherein the delay circuit is to write a logic 1 to the second input of the NAND gate when the clock signal goes high.
